(19) United States
(12) Patent Application Publication
(10) Pub. No.: US 2026/0104474 A1
(43) Pub. Date: Apr. 16, 2026

(54) METHOD AND SYSTEM FOR MEASURING LEAKAGE FLUX INDUCED EDDY CURRENT LOSS OF NANOCRYSTALLINE CORE, MEDIUM, AND DEVICE

(71) Applicant: XI'AN JIAOTONG UNIVERSITY, Xi'an (CN)

(72) Inventors: Lingyu ZHU, Xi'an (CN); Zhanlei LIU, Xi'an (CN); Shengchang JI, Xi'an (CN); Yongliang DANG, Xi'an (CN)

(21) Appl. No.: 19/354,466

(22) Filed: Oct. 9, 2025

(30) Foreign Application Priority Data
Oct. 10, 2024 (CN) 2024114088350

(51) Int. Cl. G01R 31/62; G06F 30/23

(52) U.S. Cl. CPC G01R 31/62; G06F 30/23

(57) ABSTRACT

Disclosed are a method and system for measuring a leakage flux induced eddy current loss of a nanocrystalline core, a medium, and a device. The method includes: short-circuiting a secondary winding of a nanocrystalline core high-frequency transformer, clamping two terminals of an impedance measuring instrument to a primary winding of the transformer, and measuring, by the impedance measuring instrument, an alternating current resistance R_{ac,nano} of the high-frequency transformer under a short-circuited condition; selecting a ferrite core having a same structure and size as the nanocrystalline core of the nanocrystalline core high-frequency transformer and a winding having a same structure and size as the winding of the nanocrystalline core high-frequency transformer to form a ferrite core high-frequency transformer having a same structure and size, and measuring, by the impedance measuring instrument, an alternating current resistance R_{ac,ferrite} of the ferrite core transformer under a short-circuited condition; and calculating, by the nanocrystalline core high-frequency transformer, a leakage flux distribution of the nanocrystalline core high-frequency transformer under a short-circuited condition, calculating a magnetic loss density of the nanocrystalline core, performing integration to obtain a total magnetic loss P_{c,nano} of the nanocrystalline core, and obtaining the leakage flux induced eddy current loss of the nanocrystalline core high-frequency transformer by a subtraction method.

### CROSS-REFERENCE TO RELATED APPLICATION

This application claims priority from the Chinese patent application 2024114088350 filed Oct. 10, 2024, the content of which is incorporated herein in the entirety by reference.

### TECHNICAL FIELD

The present disclosure relates to the technical field of measurement of nanocrystalline core high-frequency transformers, and in particular, a method and system for measuring a leakage flux induced eddy current loss of a nanocrystalline core, a medium, and a device.

### BACKGROUND

A high-frequency transformer includes mainly a core and a winding, and has mainly a core loss and a winding loss accordingly. Accurate calculation of the core loss of the high-frequency transformer is essential for efficiency evaluation and heat dissipation design of the high-frequency transformer. A nanocrystalline core is made by winding a nanocrystalline strip. During actual operation of a nanocrystalline core high-frequency transformer, a high eddy current on the surface of the nanocrystalline strip is induced by a normal leakage flux on the surface of the core, resulting in a leakage flux induced eddy current loss. The core loss of the nanocrystalline core high-frequency transformer is made up of traditional magnetic loss and the leakage flux induced eddy current loss. The leakage flux induced eddy current loss is an important part of the nanocrystalline core loss. Thus, it is essential to accurately measure the leakage flux induced eddy current loss of the nanocrystalline core.

A traditional two-winding open circuit method is widely applied to measurement of the core loss. By this method, a secondary winding of the transformer is opened, and voltage excitation is applied to a primary winding. A primary winding current waveform and a secondary winding voltage waveform are measured. The core loss is obtained by multiplying and integrating a secondary winding voltage and the primary winding current waveform. However, the traditional two-winding open circuit method can only measure the magnetic loss of the core, but cannot measure the leakage flux induced eddy current loss. If an infrared thermal imager is used to measure the temperature distribution of the nanocrystalline core high-frequency transformer under a short-circuited work condition, the leakage flux induced eddy current loss can be merely qualitatively reflected but cannot be quantitatively measured. At present, no relevant method can be used for quantitatively measuring the leakage flux induced eddy current loss of the nanocrystalline core.

The information disclosed in the background is merely for the convenience of understanding the background of the present disclosure, and may include information excluded from the prior art known to those of ordinary skill in the art.

### SUMMARY

In order to solve the shortcomings in the prior art, an objective of the present disclosure is to provide a method and system for measuring a leakage flux induced eddy current loss of a nanocrystalline core, a medium, and a device for quantitatively measuring the leakage flux induced eddy current loss.

In order to achieve the above objective, the present disclosure provides the following technical solution:

A method for measuring a leakage flux induced eddy current loss of a nanocrystalline core of a high-frequency transformer of the present disclosure includes:

short-circuiting a secondary winding of the nanocrystalline core high-frequency transformer, clamping two terminals of an impedance measuring instrument to a primary winding of the transformer, and measuring, by the impedance measuring instrument, an alternating current resistance R_{ac,nano} of the high-frequency transformer under a short-circuited condition, where the alternating current resistance is composed of a winding alternating current resistance R_{w,nano}, a leakage flux induced eddy current loss equivalent resistance R_{leakage}, and a core loss equivalent resistance R_{c,nano}, that is, R_{ac,nano}=R_{w,nano}+R_{leakage}+R_{c,nano};
selecting a ferrite core having a same structure and size as the nanocrystalline core of the nanocrystalline core high-frequency transformer and a winding having a same structure and size as the winding of the nanocrystalline core high-frequency transformer to form a ferrite core high-frequency transformer having a same structure and size, short-circuiting a secondary winding of the ferrite core high-frequency transformer, clamping the two terminals of the impedance measuring instrument to a primary winding of the transformer, and measuring, by the impedance measuring instrument, an alternating current resistance R_{ac,ferrite} of the ferrite core transformer under a short-circuited condition, where the alternating current resistance R_{ac,ferrite} merely includes a winding alternating current resistance R_{w,ferrite} of the ferrite core high-frequency transformer, that is, R_{ac,ferrite}=R_{w,ferrite}, a leakage magnetic field distribution in a core window of the nanocrystalline core high-frequency transformer and a leakage magnetic field distribution in a core window of the ferrite core high-frequency transformer are the same, the winding alternating current resistance of the nanocrystalline core high-frequency transformer and the winding alternating current resistance of the ferrite core high-frequency transformer are the same, and R_{w,nano}=R_{w,ferrite}=R_{ac,ferrite}; and
calculating, by the nanocrystalline core high-frequency transformer, a leakage flux distribution of the nanocrystalline core high-frequency transformer under a short-circuited condition, calculating a magnetic loss density of the nanocrystalline core, performing integration to obtain a total magnetic loss P_{c,nano} of the nanocrystalline core, and obtaining the leakage flux induced eddy current loss of the nanocrystalline core high-frequency transformer by a subtraction method.

In the method, finite element simulation software is adopted to calculate the leakage flux distribution of the nanocrystalline core high-frequency transformer under a short-circuited condition.

In the method, the finite element simulation software is COMSOL Multiphysics, Ansys, or Maxwell.

In the method, Steinmetz equation is adopted to calculate the magnetic loss density of the nanocrystalline core.

A system for measuring a leakage flux induced eddy current loss of a nanocrystalline core of a high-frequency transformer includes:
an impedance measuring instrument used for measuring, in a case where a secondary winding of the nanocrystalline core high-frequency transformer is short-circuited, an alternating current resistance R_{ac,nano} of the high-frequency transformer under a short-circuited condition by clamping two terminals of the impedance measuring instrument to a primary winding of the transformer, where the alternating current resistance is composed of a winding alternating current resistance R_{w,nano}, a leakage flux induced eddy current loss equivalent resistance R_{leakage}, and a core loss equivalent resistance R_{c,nano}, that is, R_{ac,nano}=R_{w,nano}+R_{leakage}+R_{c,nano};
a ferrite core high-frequency transformer, where a ferrite core of the ferrite core high-frequency transformer has a same structure and size as the nanocrystalline core of the nanocrystalline core high-frequency transformer and a winding of the ferrite core high-frequency transformer has a same structure and size as the winding of the nanocrystalline core high-frequency transformer, and the ferrite core high-frequency transformer is used for measuring, by the impedance measuring instrument in a case where a secondary winding of the ferrite core high-frequency transformer is short-circuited, an alternating current resistance R_{ac,ferrite} of the ferrite core transformer under a short-circuited condition by clamping the two terminals of the impedance measuring instrument to a primary winding of the transformer, where the alternating current resistance R_{ac,ferrite} merely includes a winding alternating current resistance R_{w,ferrite} of the ferrite core high-frequency transformer, that is, R_{ac,ferrite}=R_{w,ferrite}, a leakage magnetic field distribution in a core window of the nanocrystalline core high-frequency transformer and a leakage magnetic field distribution in a core window of the ferrite core high-frequency transformer are the same, the winding alternating current resistance of the nanocrystalline core high-frequency transformer and the winding alternating current resistance of the ferrite core high-frequency transformer are the same, and R_{w,nano}=R_{w,ferrite}=R_{ac,ferrite}; and
a calculating unit used for calculating a leakage flux distribution of the nanocrystalline core high-frequency transformer under a short-circuited condition, calculating a magnetic loss density of the nanocrystalline core, performing integration to obtain a total magnetic loss P_{c,nano} of the nanocrystalline core, and obtaining the leakage flux induced eddy current loss of the nanocrystalline core high-frequency transformer by a subtraction method.

In the system, the ferrite core high-frequency transformer and the nanocrystalline core high-frequency transformer have a same structure and size.

In the system, the calculating unit includes a finite element simulation unit for calculating the leakage flux distribution of the nanocrystalline core high-frequency transformer under a short-circuited condition.

In the system, the impedance measuring instrument includes an impedance analyzer or an inductance, capacitance and resistance (LCR) meter.

A computer storage medium includes computer instructions, where the computer instructions cause a computer to perform the method when run on the computer.

An electronic device includes:
a memory, a processor, and a computer program that is stored in the memory and is runnable on the processor, where
the processor implements the method when executing the program.

### Beneficial Effects

According to the method for measuring a leakage flux induced eddy current loss of a nanocrystalline core of a high-frequency transformer, the ferrite core high-frequency transformer having the same structure and size is constructed, and the alternating current resistance of the ferrite core high-frequency transformer under a short-circuited work condition is measured. Since a ferrite core loss is slight and negligible, and the leakage magnetic field distributions of the core windows of the two transformers are the same, the winding alternating current resistance of the nanocrystalline core high-frequency transformer can be approximately replaced with the winding alternating current resistance of the ferrite core high-frequency transformer in the present disclosure. Further, based on a subtraction principle, a winding loss and a magnetic loss are subtracted from a total short-circuit loss of the nanocrystalline core high-frequency transformer. In this way, the leakage flux induced eddy current loss can be quantitatively measured by the present disclosure.

What is described above is merely an overview of the technical solution of the present disclosure. In order to make the technical means of the present disclosure so clear and understandable that those of ordinary skill in the art can implement the technical means according to the contents of the description, and to make the foregoing and other objectives, features, and advantages of the present disclosure more apparent and comprehensible, description will be given blow with specific implementations of the present disclosure as examples.

### BRIEF DESCRIPTION OF DRAWINGS

To describe technical solutions in embodiments of the present disclosure or in the prior art more clearly, accompanying drawings required in the embodiments will be described briefly below. Apparently, the accompanying drawings in the following description merely show some embodiments described in the present disclosure, and those of ordinary skill in the art can still derive other accompanying drawings from these accompanying drawings.

Various other advantages and benefits of the present disclosure will become apparent to those of ordinary skill in the art by reading the following detailed description of the preferred specific implementations. The accompanying drawings of the description are merely for illustrating the preferred implementations, but should not be considered as limitation to the present disclosure. Apparently, the accompanying drawings in the following descriptions merely show some embodiments of the present disclosure, and those of ordinary skill in the art can still derive other accompanying drawings from the accompanying drawings without creative efforts. Throughout the accompanying drawings, identical reference numerals refer to identical components.

In the FIGURE:

FIG. 1 is a schematic diagram of steps of a method for measuring a leakage flux induced eddy current loss of a nanocrystalline core of a high-frequency transformer according to the present disclosure.

The present disclosure will be further explained below with reference to the accompanying drawings and in conjunction with the embodiments.

### DETAILED DESCRIPTION OF THE INVENTION

To make objectives, technical solutions, and advantages of implementations of the present disclosure clearer, the technical solutions in the implementations of the present disclosure will be clearly and completely described below in conjunction with the implementations of the present disclosure. Apparently, the implementations described are some implementations rather than all implementations of the present disclosure. All the other implementations derived by those of ordinary skill in the art from the implementations of the present disclosure without creative efforts should fall within the protection scope of the present disclosure.

Thus, the detailed description of the implementations of the present disclosure as provided in the accompanying drawings below is not intended to limit the protection scope claimed by the present disclosure, but merely denotes selected implementations of the present disclosure. All the other implementations derived by those of ordinary skill in the art from the implementations of the present disclosure without creative efforts should fall within the protection scope of the present disclosure.

It should be noted that since similar reference numerals and letters indicate similar items in the following accompanying drawings, once defined in one accompanying drawing, an item does not need to be further defined and explained in subsequent accompanying drawings.

In the description of the present disclosure, it should be understood the orientation or positional relationships indicated by the terms “center”, “longitudinal”, “lateral”, “length”, “width”, “thickness”, “up”, “down”, “front”, “rcar”, “left”, “right”, “vertical”, “horizontal”, “top”, “bottom”, “inside”, “outside”, “clockwise”, “counterclockwise”, etc. are based on the orientation or positional relationship shown in the accompanying drawings, are merely for facilitating the description of the present disclosure and simplifying the description, rather than indicating or implying that a device or element referred to must have a specific orientation or be constructed and operated in a specific orientation, and thus should not be interpreted as limitation to the present disclosure.

In addition, the terms such as “first” and “second” are used for descriptive purposes merely, and cannot be construed as indicating or implying relative importance or implicitly indicating the number of technical features indicated. Thus, features defined with “first” and “second” can explicitly or implicitly include one or more of the features. In the description of the present disclosure, “plurality” means two or more, unless otherwise specifically limited explicitly.

In the present disclosure, unless otherwise clearly specified, the terms such as “mount”, “connected”, “connection”, and “fix” should be understood broadly. For example, they can denote a fixed connection, a detachable connection, or an integrated connection, can be a direct connection or an indirect connection through an intermediate medium, and can be internal communication of two elements or interaction between two elements. Those of ordinary skill in the art can understand specific meanings of the above terms in the present disclosure based on a specific situation.

In the present disclosure, unless otherwise specified and limited, a first feature “above” or “below” a second feature indicates that the first feature may be in direct contact with the second feature, or may be in indirect contact with the second feature through another feature therebetween. Further, the first feature “above”, “over”, and “on” the second feature indicates that the first feature is exactly above or obliquely above the second feature, or merely indicates that the first feature is higher than the second feature in horizontal height. The first feature “below”, “under”, and “on a bottom of” the second feature indicates that the first feature is exactly below or and obliquely below the second feature, or merely indicates that the first feature is lower than the second feature in horizontal height.

In order to make those of ordinary skill in the art better understand the technical solution of the present disclosure, the present disclosure will be further described in detail with reference to the accompanying drawings, and the accompanying drawings do not constitute limitation to the embodiments of the present disclosure.

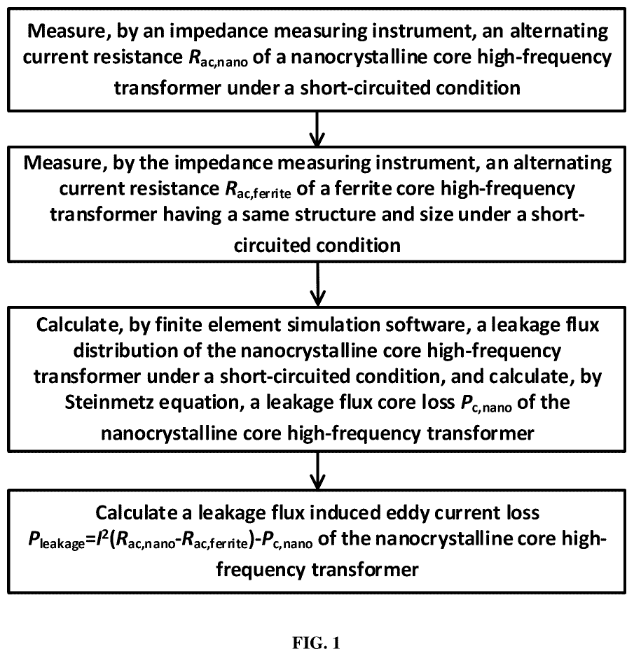

In an embodiment, as shown in FIG. 1, a method for measuring a leakage flux induced eddy current loss of a nanocrystalline core of a high-frequency transformer includes:
a secondary winding of the nanocrystalline core high-frequency transformer is short-circuited, two terminals of an impedance measuring instrument are clamped to a primary winding of the transformer, and the impedance measuring instrument measures an alternating current resistance R_{ac,nano} of the high-frequency transformer under a short-circuited condition. The alternating current resistance is composed of a winding alternating current resistance R_{w,nano}, a leakage flux induced eddy current loss equivalent resistance R_{leakage}, and a core loss equivalent resistance R_{c,nano}, that is, R_{ac,nano}=R_{w,nano}+R_{leakage}+R_{c,nano};
a ferrite core having a same structure and size as the nanocrystalline core of the nanocrystalline core high-frequency transformer and a winding having a same structure and size as the winding of the nanocrystalline core high-frequency transformer are selected to form a ferrite core high-frequency transformer having a same structure and size, a secondary winding of the ferrite core high-frequency transformer is short-circuited, the two terminals of the impedance measuring instrument are clamped to a primary winding of the transformer, and the impedance measuring instrument measures an alternating current resistance R_{ac,ferrite} of the ferrite core transformer under a short-circuited condition. The alternating current resistance R_{ac,ferrite} merely includes a winding alternating current resistance R_{w,ferrite} of the ferrite core high-frequency transformer, that is, R_{ac,ferrite}=R_{w,ferrite}, a leakage magnetic field distribution in a core window of the nanocrystalline core high-frequency transformer and a leakage magnetic field distribution in a core window of the ferrite core high-frequency transformer are the same, the winding alternating current resistance of the nanocrystalline core high-frequency transformer and the winding alternating current resistance of the ferrite core high-frequency transformer are the same, and R_{w,nano}=R_{w,ferrite}=R_{ac,ferrite}; and

a leakage flux distribution of the nanocrystalline core high-frequency transformer under a short-circuited condition is calculated, a magnetic loss density of the nanocrystalline core is calculated, integration is performed to obtain a total magnetic loss P_{c,nano} of the nanocrystalline core, and the leakage flux induced eddy current loss of the nanocrystalline core high-frequency transformer is obtained by a subtraction method:

$${P}_{leakage} = {I}^{2} ( {R}_{ac , nano} - {R}_{ac , ferrite} ) - {P}_{c , nano} .$$

In the formula, I denotes a short-circuit current.

In a preferred implementation of the method, the impedance measuring instrument includes an impedance analyzer or an inductance, capacitance and resistance (LCR) meter.

In a preferred implementation of the method, finite element simulation software is adopted to calculate the leakage flux distribution of the nanocrystalline core high-frequency transformer under a short-circuited condition.

In a preferred implementation of the method, the finite element simulation software is COMSOL Multiphysics, Ansys, or Maxwell.

In a preferred implementation of the method, Steinmetz equation is adopted to calculate the magnetic loss density of the nanocrystalline core.

In an embodiment, the method includes:
(1) The secondary winding of the nanocrystalline core high-frequency transformer is short-circuited, the two terminals of the impedance measuring instrument (such as the impedance analyzer or the LCR meter) are clamped to the primary winding of the transformer, and the impedance measuring instrument measures the alternating current resistance R_{ac,nano} of the nanocrystalline core high-frequency transformer under a short-circuited condition. The alternating current resistance is composed of the winding alternating current resistance R_{w,nano}, the leakage flux induced eddy current loss equivalent resistance R_{leakage}, and the core loss equivalent resistance R_{c,nano}. That is, R_{ac,nano}=R_{w,nano}+R_{leakage}+R_{c,nano}.
(2) The ferrite core and the winding that have the same structure and size are selected to form the ferrite core high-frequency transformer having the same structure and size, the secondary winding of the ferrite core high-frequency transformer is short-circuited, the two terminals of the impedance measuring instrument (such as the impedance analyzer or the LCR meter) are clamped to the primary winding of the transformer, and the impedance measuring instrument measures the alternating current resistance R_{ac,ferrite} of the ferrite core transformer under a short-circuited condition. A ferrite core magnetic loss under a short-circuited work condition is slight and negligible. The R_{ac,ferrite} merely includes the winding alternating current resistance R_{w,ferrite} of the ferrite core high-frequency transformer, that is, R_{ac,ferrite}=R_{w,ferrite}. Since the structures and the sizes of the nanocrystalline core transformer and the ferrite core transformer are completely the same, the leakage magnetic field distributions in the core windows of the two transformers are the same, the winding alternating current resistances of the two transformer are the same, and R_{w,nano}=R_{w,ferrite}=R_{ac,ferrite}.
(3) The finite element simulation software (such as COMSOL Multiphysics, Ansys, and Maxwell) is adopted to calculate the leakage flux distribution of the nanocrystalline core high-frequency transformer under a short-circuited condition, the Steinmetz equation is adopted to calculate the magnetic loss density of the nanocrystalline core, and then integration is performed to obtain the total magnetic loss P_{c,nano} of the nanocrystalline core.
(4) The leakage flux induced eddy current loss P_{leakage}=I²(R_{ac,nano}−R_{ac,ferrite})−P_{c,nano} of the nanocrystalline core high-frequency transformer is obtained by the subtraction method.

In an embodiment, a system for measuring a leakage flux induced eddy current loss of a nanocrystalline core of a high-frequency transformer includes:
an impedance measuring instrument used for measuring, in a case where a secondary winding of the nanocrystalline core high-frequency transformer is short-circuited, an alternating current resistance R_{ac,nano} of the high-frequency transformer under a short-circuited condition by clamping two terminals of the impedance measuring instrument to a primary winding of the transformer. The alternating current resistance is composed of a winding alternating current resistance R_{w,nano}, a leakage flux induced eddy current loss equivalent resistance R_{leakage}, and a core loss equivalent resistance R_{c,nano}, that is, R_{ac,nano}=R_{w,nano}+R_{leakage}+R_{c,nano};
a ferrite core high-frequency transformer. A ferrite core of the ferrite core high-frequency transformer has a same structure and size as the nanocrystalline core of the nanocrystalline core high-frequency transformer and a winding of the ferrite core high-frequency transformer has a same structure and size as the winding of the nanocrystalline core high-frequency transformer. The ferrite core high-frequency transformer is used for measuring, by the impedance measuring instrument in a case where a secondary winding of the ferrite core high-frequency transformer is short-circuited, an alternating current resistance R_{ac,ferrite} of the ferrite core transformer under a short-circuited condition by clamping the two terminals of the impedance measuring instrument to a primary winding of the transformer. The alternating current resistance R_{ac,ferrite} merely includes a winding alternating current resistance R_{w,ferrite} of the ferrite core high-frequency transformer, that is, R_{ac,ferrite}=R_{w,ferrite}, a leakage magnetic field distribution in a core window of the nanocrystalline core high-frequency transformer and a leakage magnetic field distribution in a core window of the ferrite core high-frequency transformer are the same, the winding alternating current resistance of the nanocrystalline core high-frequency transformer and the winding alternating current resistance of the ferrite core high-frequency transformer are the same, and R_{w,nano}=R_{w,ferrite}=R_{ac,ferrite}; and
a calculating unit used for calculating a leakage flux distribution of the nanocrystalline core high-frequency transformer under a short-circuited condition, calculating a magnetic loss density of the nanocrystalline core, performing integration to obtain a total magnetic loss P_{c,nano} of the nanocrystalline core, and obtaining the leakage flux induced eddy current loss of the nanocrystalline core high-frequency transformer by a subtraction method:

$${P}_{leakage} = {I}^{2} ( {R}_{ac , nano} - {R}_{ac , ferrite} ) - {P}_{c , nano} .$$

In the formula, I denotes a short-circuit current.

In the system, the ferrite core high-frequency transformer and the nanocrystalline core high-frequency transformer have a same structure and size.

In the system, the calculating unit includes a finite element simulation unit for calculating the leakage flux distribution of the nanocrystalline core high-frequency transformer under a short-circuited condition.

In the system, the impedance measuring instrument includes an impedance analyzer or an LCR meter.

A computer storage medium includes computer instructions. The computer instructions cause a computer to perform the method when run on the computer.

An electronic device includes:
a memory, a processor, and a computer program that is stored in the memory and is runnable on the processor.

The processor implements the method when executing the program.

Although the implementation solutions of the present disclosure have been described above in conjunction with the accompanying drawings, the present disclosure is not limited to the specific implementation solutions and application fields, and the specific implementation solutions are merely illustrative, instructive rather than limitative. Those of ordinary skill in the art can further make many forms under the inspiration of this description and without departing from the protection scope of the claims of the present disclosure. Those forms are still protected by the present disclosure.

1. A method for measuring a leakage flux induced eddy current loss of a nanocrystalline core of a high-frequency transformer, comprising:
short-circuiting a secondary winding of the nanocrystalline core high-frequency transformer, clamping two terminals of an impedance measuring instrument to a primary winding of the nanocrystalline core high-frequency transformer, and measuring, by the impedance measuring instrument, an alternating current resistance R_{ac,nano} of the high-frequency transformer under a short-circuited condition, wherein the alternating current resistance is composed of a winding alternating current resistance R_{w,nano}, a leakage flux induced eddy current loss equivalent resistance R_{leakage}, and a core loss equivalent resistance R_{c,nano}, that is,
$${R}_{ac , nano} = {R}_{w , nano} + {R}_{leakage} + {R}_{c , nano} ;$$
selecting a ferrite core having a same structure and size as the nanocrystalline core of the nanocrystalline core high-frequency transformer and a winding having a same structure and size as the winding of the nanocrystalline core high-frequency transformer to form a ferrite core high-frequency transformer having a same structure and size, short-circuiting a secondary winding of the ferrite core high-frequency transformer, clamping the two terminals of the impedance measuring instrument to a primary winding of the ferrite core high-frequency transformer, and measuring, by the impedance measuring instrument, an alternating current resistance R_{ac,ferrite} of the ferrite core transformer under a short-circuited condition, wherein the alternating current resistance R_{ac,ferrite} merely comprises a winding alternating current resistance R_{w,ferrite} of the ferrite core high-frequency transformer, that is, R_{ac,ferrite}=R_{w,ferrite}, a leakage magnetic field distribution in a core window of the nanocrystalline core high-frequency transformer and a leakage magnetic field distribution in a core window of the ferrite core high-frequency transformer are the same, the winding alternating current resistance of the nanocrystalline core high-frequency transformer and the winding alternating current resistance of the ferrite core high-frequency transformer are the same, and R_{w,nano}=R_{w,ferrite}=R_{ac,ferrite}; and
calculating a leakage flux distribution of the nanocrystalline core high-frequency transformer under a short-circuited condition, calculating a magnetic loss density of the nanocrystalline core, performing integration to obtain a total magnetic loss P_{c,nano} of the nanocrystalline core, and obtaining the leakage flux induced eddy current loss of the nanocrystalline core high-frequency transformer by a subtraction method.

2. The method according to claim 1, wherein finite element simulation software is adopted to calculate the leakage flux distribution of the nanocrystalline core high-frequency transformer under a short-circuited condition.

3. The method according to claim 2, wherein the finite element simulation software is COMSOL Multiphysics, Ansys, or Maxwell.

4. The method according to claim 1, wherein Steinmetz equation is adopted to calculate the magnetic loss density of the nanocrystalline core.

5. A system for measuring a leakage flux induced eddy current loss of a nanocrystalline core of a high-frequency transformer, comprising:
an impedance measuring instrument used for measuring, in a case where a secondary winding of the nanocrystalline core high-frequency transformer is short-circuited, an alternating current resistance R_{ac,nano} of the high-frequency transformer under a short-circuited condition by clamping two terminals of the impedance measuring instrument to a primary winding of the transformer, wherein the alternating current resistance is composed of a winding alternating current resistance R_{w,nano}, a leakage flux induced eddy current loss equivalent resistance R_{leakage}, and a core loss equivalent resistance R_{c,nano}, that is, R_{ac,nano}=R_{w,nano}+R_{leakage}+R_{c,nano};
a ferrite core high-frequency transformer, wherein a ferrite core and a winding of the ferrite core high-frequency transformer have a same structure and size as the nanocrystalline core and the winding of the nanocrystalline core high-frequency transformer, and the ferrite core high-frequency transformer is used for measuring, by the impedance measuring instrument in a case where a secondary winding of the ferrite core high-frequency transformer is short-circuited, an alternating current resistance R_{ac,ferrite} of the ferrite core transformer under a short-circuited condition by clamping the two terminals of the impedance measuring instrument to a primary winding of the transformer, wherein the alternating current resistance R_{ac,ferrite} merely comprises a winding alternating current resistance R_{w,ferrite} of the ferrite core high-frequency transformer, that is, R_{ac,ferrite}=R_{w,ferrite}, a leakage magnetic field distribution in a core window of the nanocrystalline core high-frequency transformer and a leakage magnetic field distribution in a core window of the ferrite core high-frequency transformer are the same, the winding alternating current resistance of the nanocrystalline core high-frequency transformer and the winding alternating current resistance of the ferrite core high-frequency transformer are the same, and R_{w,nano}=R_{w,ferrite}=R_{ac,ferrite}; and
a calculating unit used for calculating a leakage flux distribution of the nanocrystalline core high-frequency transformer under a short-circuited condition, calculating a magnetic loss density of the nanocrystalline core, performing integration to obtain a total magnetic loss P_{c,nano} of the nanocrystalline core, and obtaining the leakage flux induced eddy current loss of the nanocrystalline core high-frequency transformer by a subtraction method.

6. The system according to claim 5, wherein the ferrite core high-frequency transformer and the nanocrystalline core high-frequency transformer have a same structure and size.

7. The system according to claim 6, wherein the calculating unit comprises a finite element simulation unit for calculating the leakage flux distribution of the nanocrystalline core high-frequency transformer under a short-circuited condition.

8. The system according to claim 5, wherein the impedance measuring instrument comprises an impedance analyzer or an inductance, capacitance and resistance (LCR) meter.

9. A computer storage medium, comprising computer instructions, wherein the computer instructions cause a computer to perform the method according to claim 1 when run on the computer.

10. An electronic device, comprising:
a memory, a processor, and a computer program that is stored in the memory and is runnable on the processor, wherein the processor implements the method according to claim 1 when executing the program.

11. The computer storage medium of claim 9, wherein finite element simulation software is adopted to calculate the leakage flux distribution of the nanocrystalline core high-frequency transformer under a short-circuited condition.

12. The computer storage medium of claim 11, wherein the finite element simulation software is COMSOL Multiphysics, Ansys, or Maxwell.

13. The computer storage medium of claim 9, wherein Steinmetz equation is adopted to calculate the magnetic loss density of the nanocrystalline core.

14. The electronic device of claim 10, wherein finite element simulation software is adopted to calculate the leakage flux distribution of the nanocrystalline core high-frequency transformer under a short-circuited condition.

15. The electronic device of claim 14, wherein the finite element simulation software is COMSOL Multiphysics, Ansys, or Maxwell.

16. The electronic device of claim 10, wherein Steinmetz equation is adopted to calculate the magnetic loss density of the nanocrystalline core.
